(19) United States
(12) Patent Application Publication
(10) Pub. No.: US 2015/0094966 A1
(43) Pub. Date: Apr. 2, 2015

(54) QUADRATURE-BASED VOLTAGE EVENTS DETECTION METHOD

(71) Applicants: KING ABDULAZIZ CITY FOR SCIENCE AND TECHNOLOGY, Riyadh (SA); KING FAHD UNIVERSITY OF PETROLEUM AND MINERALS, Dhahran (SA)

(72) Inventors: MOHAMMAD ALI ABIDO, DHAHRAN (SA); FOUAD RASHED FOUAD ZARO, DHAHRAN (SA)

(73) Assignees: KING ABDULAZIZ CITY FOR SCIENCE AND TECHNOLOGY, Riyadh (SA); KING FAHD UNIVERSITY OF PETROLEUM AND MINERALS, Dhahran (SA)

(21) Appl. No.: 14/043,756

(22) Filed: Oct. 1, 2013

(51) Int. Cl. G01R 31/02

(52) U.S. Cl. CPC G01R 31/02
USPC 702/58

(57) ABSTRACT

The quadrature-based voltage events detection method accurately characterizes magnitude and duration of short duration voltage variations, such as sag, swell and interruption. The short duration voltage events are quantified by calculating the rms voltage. The present method utilizes a quadrature procedure to calculate the rms values for power quality event detection. Parameters that are most influenced by variations in rms voltage are used for event detection. Experimental results demonstrate the superiority, accuracy, and robustness of the quadrature method for all cases considered.

### BACKGROUND OF THE INVENTION

1. Field of the Invention

The present invention relates to power quality systems, and particularly to a quadrature-based voltage events detection method.

2. Description of the Related Art

Power quality (PQ) monitoring is the process of gathering the necessary data about voltages and currents for control and decision-making actions. A growing concern with PQ is the increasing application of power electronics devices in power systems that can cause high disturbances.

Short-duration voltage variations include interruption, sag (dip), and swell. Such events are always caused by fault conditions, energizing large loads that require high starting currents, or intermittent loose connections in power wiring. Voltage interruption occurs when the supply voltage decreases to less than 10% of nominal rms (root mean square) voltage for a time period not exceeding 1.0 min. Voltage sag is a decrease in rms voltage to the range between 10% and 90% of nominal rms voltage for durations from 0.5 cycles to 1.0 minute. A voltage swell is the converse to the sag, where there is an increase in rms voltage above 110% to 180% of nominal voltage for durations of 0.5 cycle to 1.0 minute. Voltage events are usually associated with system faults, switching on/off heavy loads and capacitor banks, incorrect settings off-tap changers in power substations, equipment failures, control malfunctions, and large load changes.

According to IEEE Standard 1159-2009 and IEC standard 61000-4-30, short-duration voltage variations are variations of the rms value of the voltage for short time intervals. Based on this concept, the characterization of short-duration voltage events, in terms of the duration and amplitude, should be quantified using the rms voltage, not the instantaneous voltage. They defined the Urms (½) magnitude as the rms voltage measured over one cycle, commencing at a fundamental cross zero, and refreshed each half-cycle.

In general, some PQ analyzers do not obtain satisfactory results during testing. This can be attributed to rms value and average value calculation methods. Although simple, rms methods suffer from dependency on the window length and the time interval for updating the values. Depending on the selection of these two parameters, the magnitude and the duration of a voltage event can be very different. Accurate and fast measurement of the instantaneous electrical quantities in electric power systems plays a very important role in PQ studies, and a robust protocol for the rms values calculation of a voltage waveform must be developed.

Thus, a quadrature-based voltage events detection method solving the aforementioned problems is desired.

### SUMMARY OF THE INVENTION

The quadrature-based voltage events detection method accurately characterizes the magnitude and duration of short-lived voltage variations, such as sag, swell and interruption. These short-duration voltage events are quantified by calculating the rms voltage. The present method utilizes a quadrature procedure to calculate the rms values for power quality event detection. Parameters that are most influenced by variations in rms voltage are used for event detection. Experimental results demonstrate the superiority, accuracy, and robustness of the quadrature method for all cases considered.

These and other features of the present invention will become readily apparent upon further review of the following specification and drawings.

### BRIEF DESCRIPTION OF THE DRAWINGS

FIG. 1A is a diagram showing a window sliding technique for calculating rms voltage using digital signal processing techniques in which the sampling window (N samples per cycle, one cycle per sampling window) slides one sample to the right with each successive rms voltage measurement.

FIG. 1B is a diagram showing a window sliding technique for calculating rms voltage using digital signal processing techniques in which the sampling window (N samples per cycle, one cycle per sampling window) slides one-half cycle to the right with each successive rms voltage measurement.

FIG. 1C is a diagram showing a window sliding technique for calculating rms voltage using digital signal processing techniques in which the sampling window (N samples per cycle, one cycle per sampling window) slides one cycle to the right with each successive rms voltage measurement.

FIG. 2A is a diagram showing a window sliding technique for calculating rms voltage using digital signal processing techniques in which the sampling window (N samples per cycle, one-half cycle per sampling window) slides one sample to the right with each successive rms voltage measurement.

FIG. 2B is a diagram showing a window sliding technique for calculating rms voltage using digital signal processing techniques in which the sampling window (N samples per cycle, one cycle per sampling window) slides one-half cycle to the right with each successive rms voltage measurement.

FIG. 3 is a waveform plot showing a two-sample quadrature measurement of rms voltage.

FIG. 4 is a screenshot showing a power quality system.

FIG. 5 is a block diagram of a power quality system.

FIG. 6 is a waveform plot showing quadrature sample to sample sliding.

FIG. 7A is a waveform plot showing an N sample per cycle method sliding window of each sample.

FIG. 7B is a waveform plot showing a half-cycle sliding window.

FIG. 7C is a waveform plot showing a cycle sliding window.

FIG. 8A is a waveform plot showing rms calculation using N/2 sample per cycle sliding window.

FIG. 8B is a waveform plot showing rms calculation using N/2 sample per ½ cycle sliding window.

FIG. 9A is a waveform plot showing instantaneous voltage sag waveform.

FIG. 9B is a waveform plot showing rms track for the voltage sag waveform.

FIG. 10A is a waveform plot showing the voltage interruption waveform.

FIG. 10B is a waveform plot showing the rms track for the voltage interruption waveform.

FIG. 11A is a waveform plot showing the voltage swell waveform.

FIG. 11B is a waveform plot showing the rms track for the voltage swell waveform.

FIG. 12 is a waveform plot showing event starts at any point of the voltage waveform.

FIG. 13A is an instantaneous voltage sag waveform plot.

FIG. 13B is an instantaneous voltage sag rms tracking plot.

FIG. 14A is a voltage interruption waveform plot.

FIG. 14B is a voltage interruption rms tracking plot.

FIG. 15A is a voltage swell waveform plot.

FIG. 15B is a voltage swell rms tracking plot.

Similar reference characters denote corresponding features consistently throughout the attached drawings.

### DETAILED DESCRIPTION OF THE PREFERRED EMBODIMENTS

The quadrature-based voltage events detection method accurately characterizes the magnitude and duration of short duration voltage variations, such as sag, swell and interruption. The short duration voltage events are quantified by calculating the rms voltage. The present method utilizes a quadrature procedure to calculate the rms values for power quality event detection. Parameters that are most influenced by variations in rms voltage are used for event detection. Experimental results demonstrate the superiority, accuracy, and robustness of the quadrature method for all cases considered.

Generally, the rms value can be calculated if the waveform is sampled as follows:

$${V}_{r m s} = \sqrt{\frac{1}{N} {\sum }_{i = 1}^{N} {v}_{i}^{2}} \qquad ( 1 )$$

where N is the number of samples per cycle and νᵢ is the sampled voltages in time domain. From equation (1), it is clear that rms value calculation using one cycle sampling windows of the voltage waveform with different sliding window methods, or rms value calculation using half-cycle sampling windows of the voltage waveform with different sliding window methods, can be used to calculate the rms value of a voltage waveform.

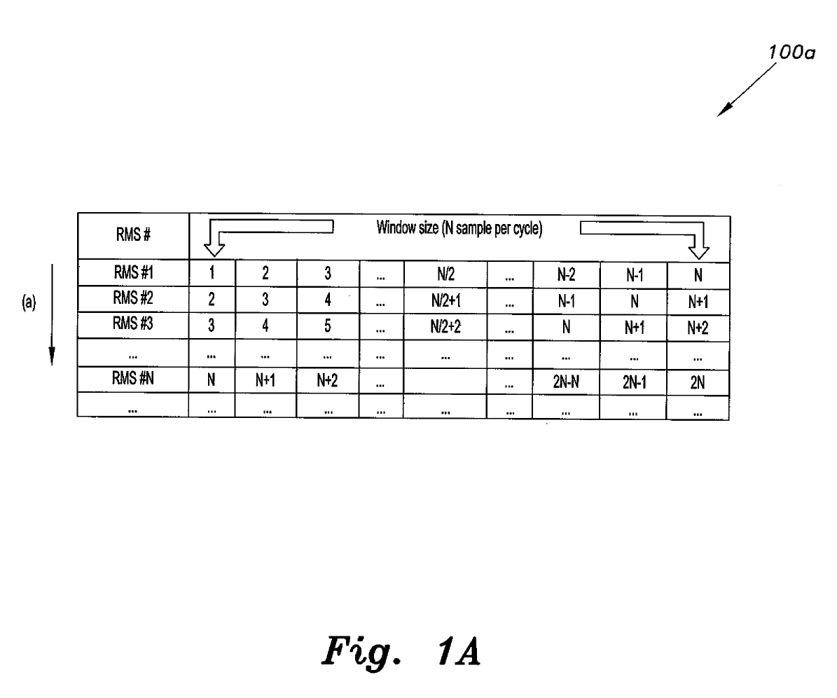

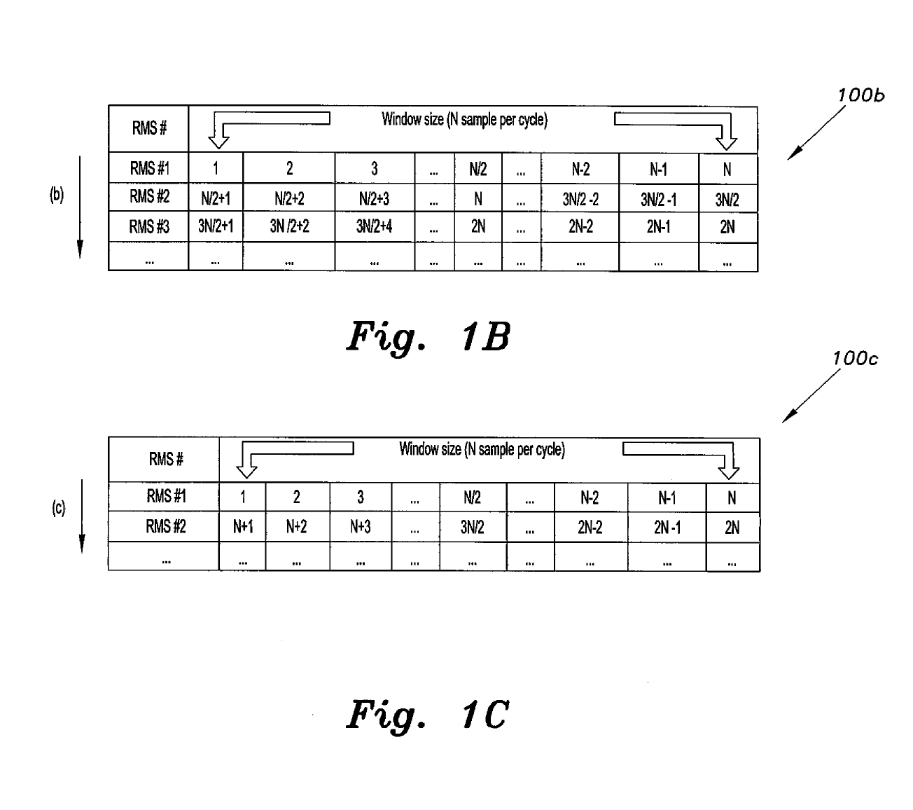

FIGS. 1A-1C, diagrams 100a through 100c, respectively, show the calculation methods of rms values using N samples per-cycle with different refresh rates, e.g., each sample, each half cycle, and each one cycle. Thus, in FIG. 1A, the sampling window is one cycle, with N samples being taken per cycle. The first rms measurement, RMS #1, begins with sample 1. The sampling window then slides to the right by one sample, so that the second rms measurement, RMS #2, begins with sample 2, the sampling window again slides to the right by one sample so that the third rms measurement, RMS #3, begins with sample 3, etc. a similar technique is used for the sampling windows shown in FIGS. 1B-1C.

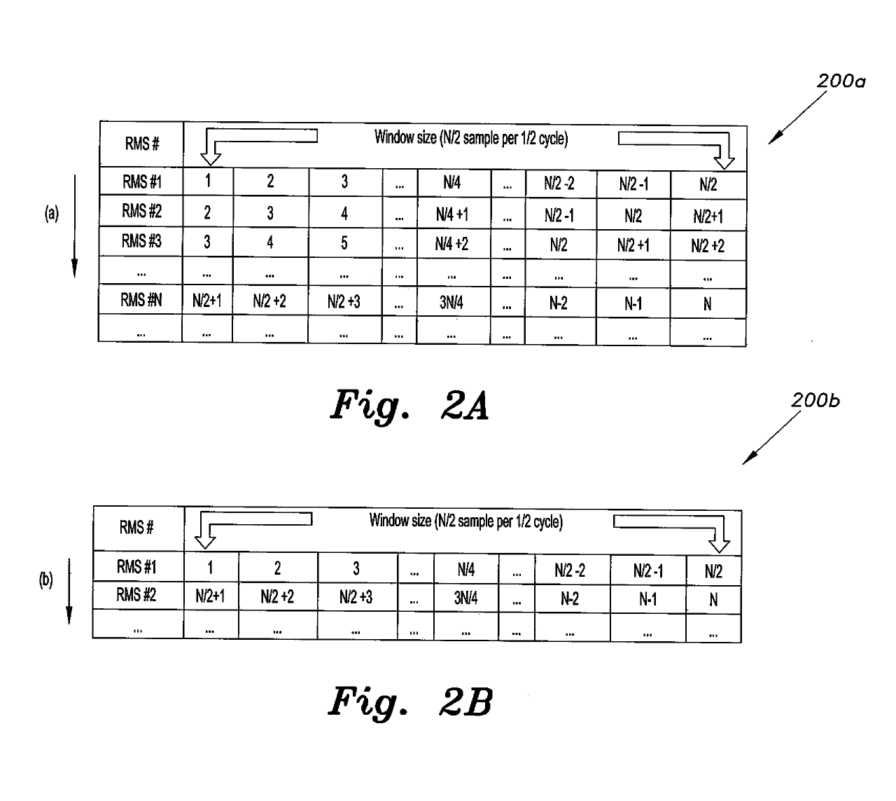

In FIGS. 2A-2B, diagrams 200a and 200b show the sliding window calculation method of rms values wherein each sampling window is only one-half cycle long. It is well-known that methods of sliding window sampling that vary by the length of the slide, as well as variations in the sampling window size, have an important effect in calculating and updating the rms values. Most of the existing monitoring devices obtain the magnitude variation from the rms value of voltages.

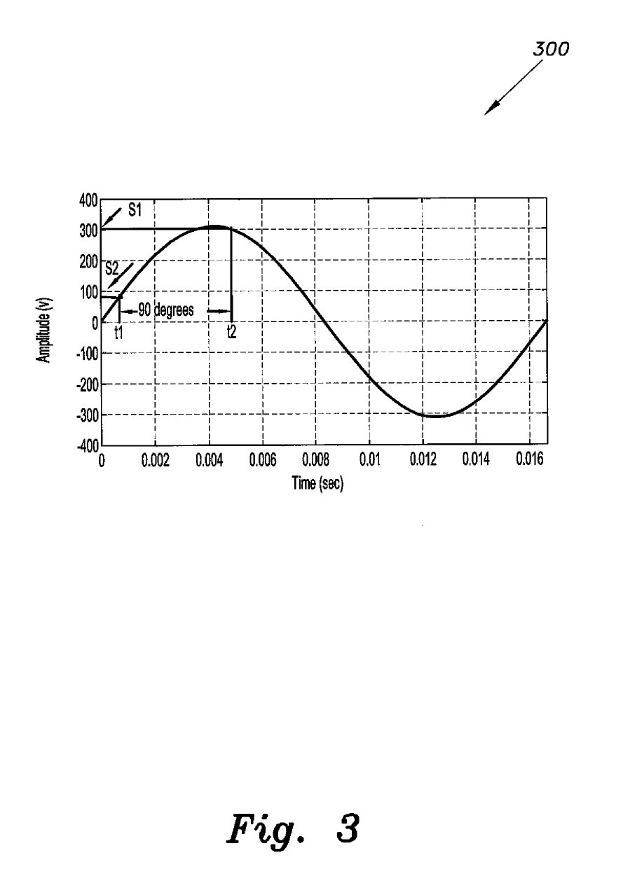

Similar to the conventional methods, the present quadrature-based method calculates the rms value based on the sampled time-domain voltage. However, it uses only two samples having a 90° shift (i.e., one-quarter cycle time difference) between them, as shown in plot 300 of FIG. 3. This can be explained according to equations (2) through (9) as follows:

$$\begin{matrix}v ( t ) = {V}_{p} sin ( wt ) & ( 2 ) \\ {S}_{1} = {V}_{p} sin ( θ ) & ( 3 ) \\ {S}_{2} = {V}_{p} sin ( θ + π / 2 ) & ( 4 ) \\ {S}_{2} = {V}_{p} cos ( θ ) & ( 5 ) \\ {S}_{1}^{2} + {S}_{2}^{2} = {V}_{p}^{2} ( {sin}^{2} ( θ ) + {cos}^{2} ( θ ) ) & ( 6 ) \\ \sqrt{{S}_{1}^{2} + {S}_{2}^{2}} = \sqrt{{V}_{p}^{2}} & ( 7 ) \\ \sqrt{{S}_{1}^{2} + {S}_{2}^{2}} = {V}_{p} & ( 8 ) \\ {V}_{r m s} = \frac{{V}_{p}}{\sqrt{2}} = \frac{\sqrt{{S}_{1}^{2} + {S}_{2}^{2}}}{\sqrt{2}} & ( 9 )\end{matrix}$$

where v(t), Vₚ and Vᵣₘₛ are instantaneous, peak, and rms values of the voltage waveform, and S₁ and S₂ are the first and second samples, respectively. The present method has been implemented in Matlab and LabVIEW to demonstrate its effectiveness theoretically as well as experimentally.

An experimental setup to test the present method includes a workstation running LabVIEW 2011, National Instrument CompactRIO-9024, programmable AC source, programmable electronic loads, and panels housing current transformers with load connectors.

A Programmable AC source provides powerful functions to simulate voltage disturbance conditions, such as interruption, sag, and swell. Programmable electronic loads can simulate loading conditions under different crest factor and varying power factors with real time compensation, even when the voltage waveform is distorted. This special feature provides real world simulation capability and prevents overstressing, resulting in reliable and unbiased test results. The CompactRIO (cRIO) includes a Real-Time Controller, which contains an industrial processor that reliably and deterministically executes LabVIEW Real-Time applications and offers multi-rate control, execution tracing, onboard data logging, and communication with peripherals; a reconfigurable reconfigurable I/O (RIO) FPGA directly connected to the I/O modules for high-performance access to the I/O circuitry of each module and unlimited timing, triggering, and synchronization flexibility; and I/O Modules such as the NI-9225 module, which can measure directly from the line up to 300 V rms; and NI-9227, which is a 4-channel, 5 A rms current measurement module. Current transformers (100/5 A) are used to measure the load currents directly with this module. LabVIEW 2011 was selected, since it is a graphical-based programming language. Algorithms were developed for data acquisition at the specified sampling frequency and processed real-time using the real-time controller to monitor line properties.

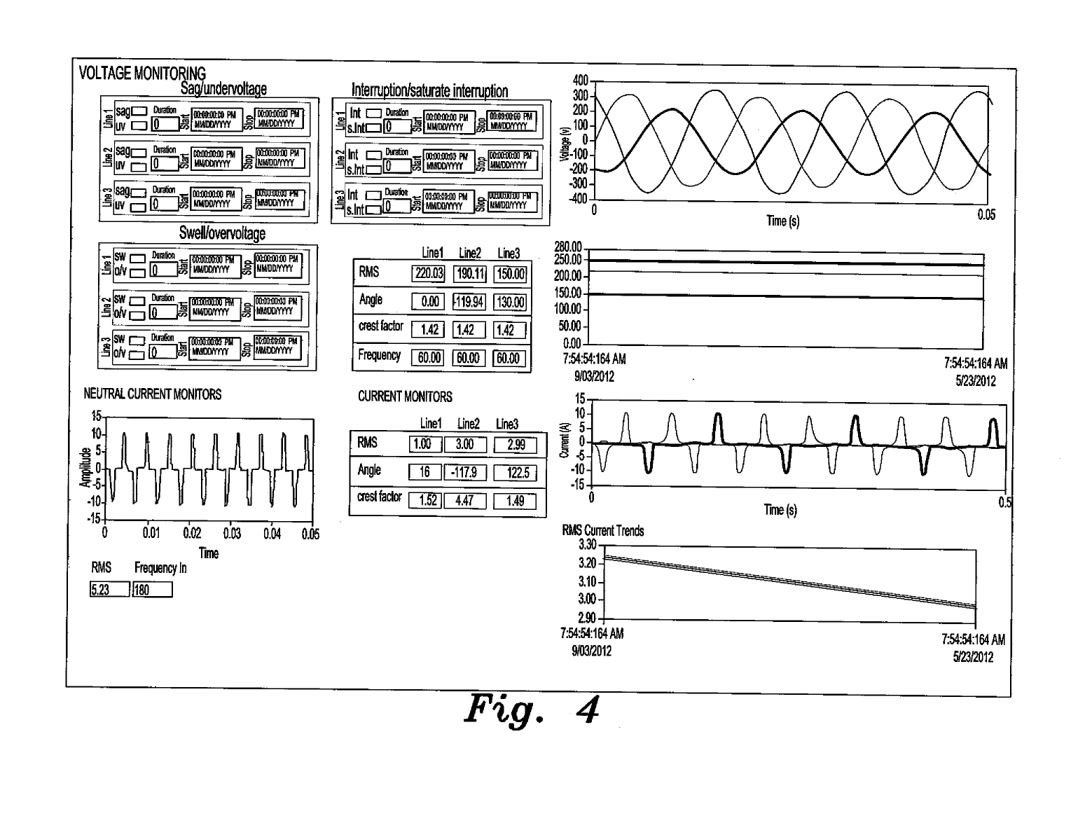

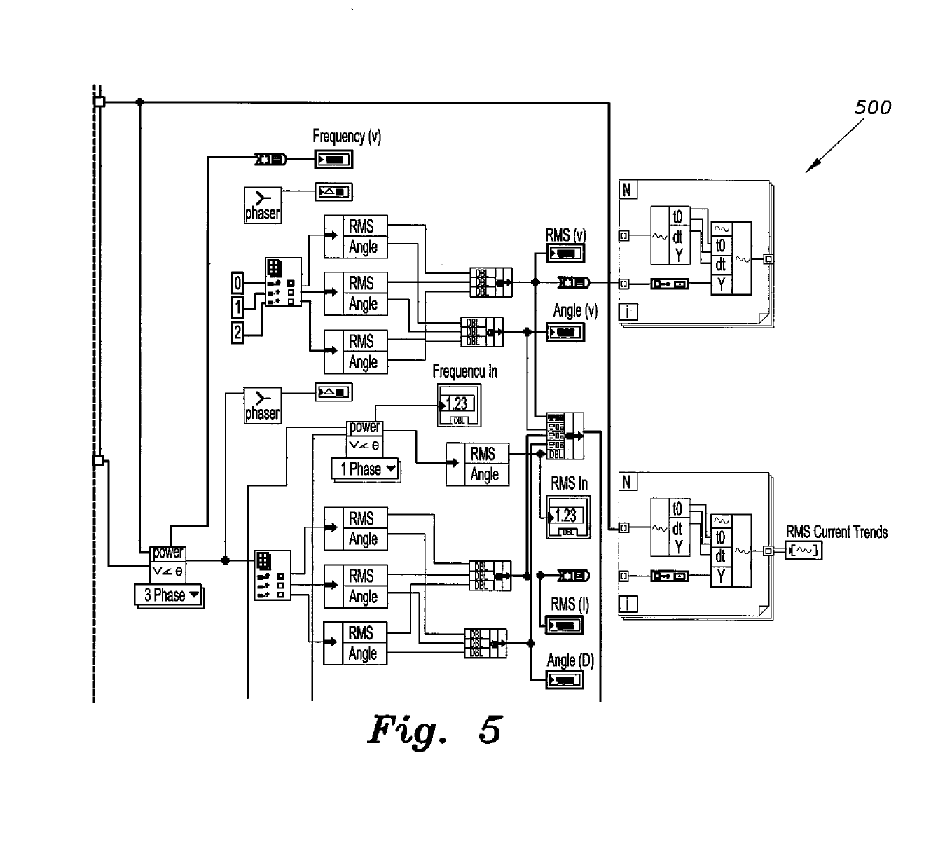

FIGS. 4 and 5 show the front panel monitoring screen 400 of the voltage events and the block diagram of virtual instrument (VI) 500 of the PQ monitoring system developed on LabVIEW platform, respectively. Voltage events characterization and classification and the details of the event, such as in which phase the event is occurring, event type, starting time, stop time, event duration, and the rms voltage of the event, can be displayed on the front panel.

To examine the effectiveness and robustness of the present quadrature method for estimating the magnitude and duration of the voltage events, three voltage events have been considered: sag, interruption and swell. The results of the present method are compared with the conventional rms calculation methods. A 6-cycles event is applied. The sampling rate considered is 166 samples per cycle.

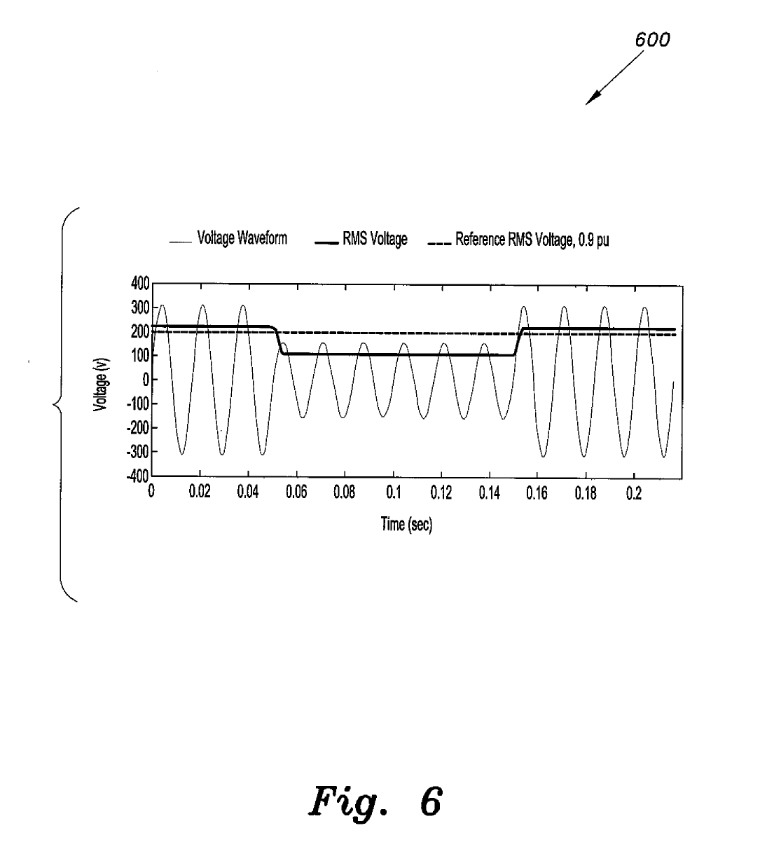

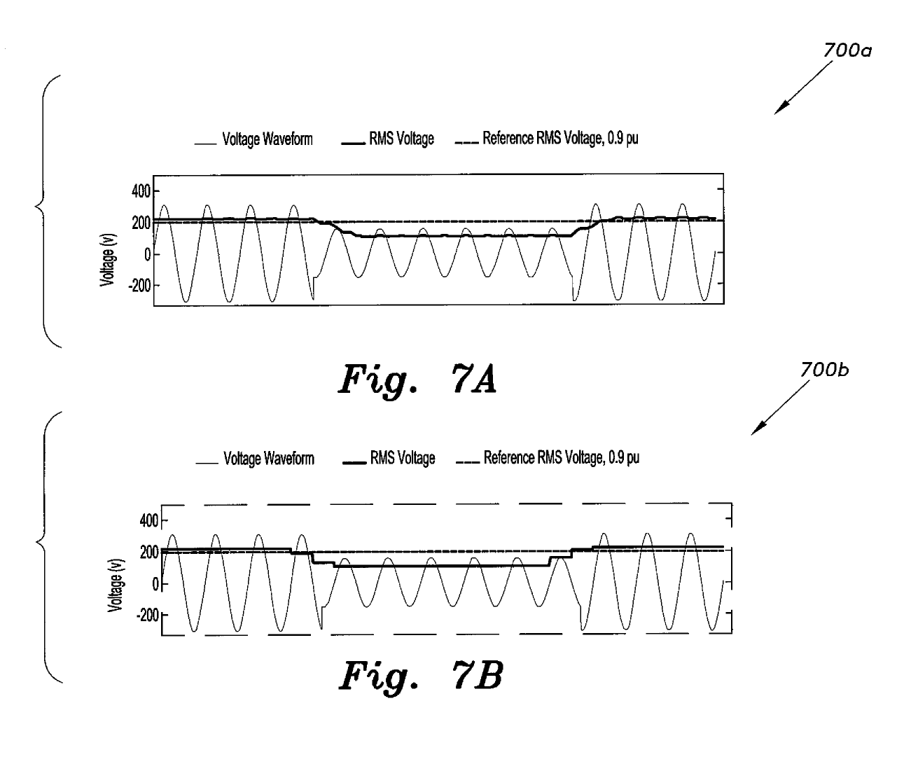

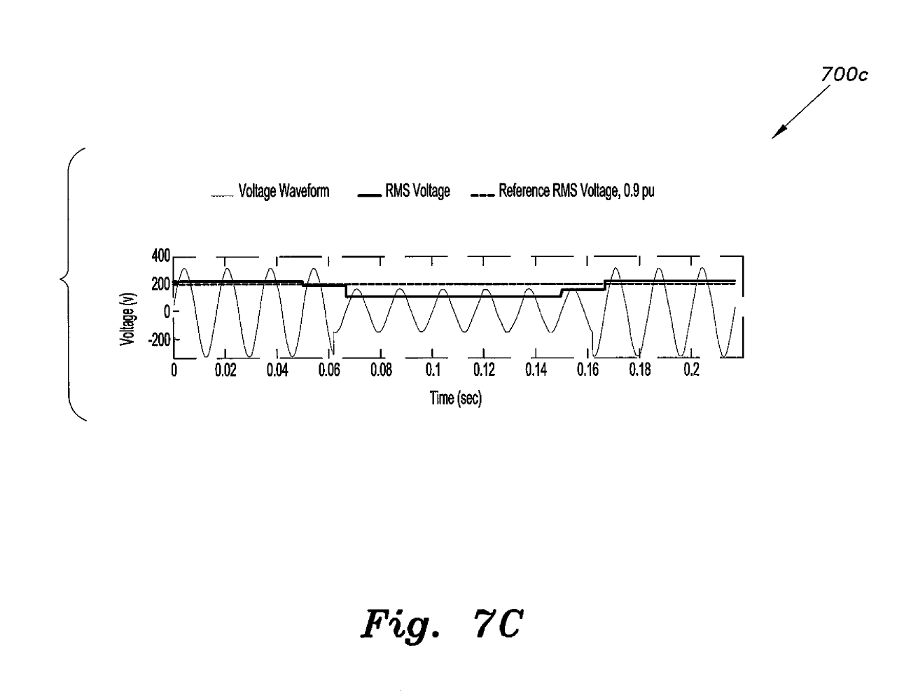

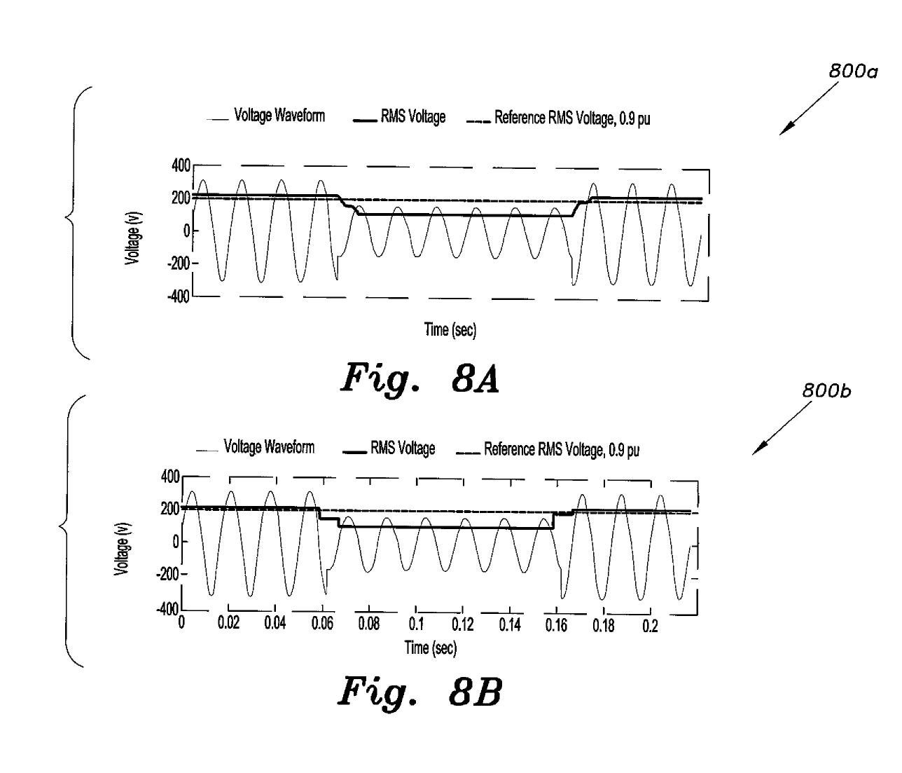

According to IEEE definition, voltage sag occurs when rms voltage decreases to a value between 10% and 90% of nominal rms voltage for duration from 0.5 cycles to 1.0 min. A 50% reduction in the voltage magnitude is considered. For testing purposes of the present quadrature method, a sample-to-sample sliding window method is used to calculate the rms values of the voltage waveform, with the multiple calculations of rms value being averaged by mean-square. Plot 600 of FIG. 6 shows the performance of the present method if the event starts at 0°. In this case, the detected duration by the present method is 101.34 ms, with a deviation of 1.34 ms from the exact duration of 100 ms. For comparison purposes, the conventional sliding window methods as shown in FIGS. 1A-1C, have been employed to calculate the rms values of the voltage waveform for the same event. FIGS. 7A-7C, plots 700a through 700c, respectively, present the results obtained by N sample per cycle method with various sliding window sizes. The best result was achieved for the case of sample-to-sample sliding window, where the duration of the event is estimated as 108.24 ms. This gives rise to an error 8.24 ms, which is too high as compared to that of the present quadrature method. The results of the half cycle sliding window and the complete cycle sliding window methods are less accurate, as the estimated duration of the event is 108.34 ms and 116.67 ms, respectively. FIGS. 8A-8B, plots 800a-800b, present the results obtained by N/2 sample per half-cycle method with various sliding windows. The best result was achieved for the case of sample-to-sample sliding window, where the duration of the event is estimated as 105.65 ms, with an error of 5.65 ms. The present method is much more accurate than the conventional methods. The best results of the three methods: Quadrature, N sample per cycle and N/2 sample per cycle have been achieved with sample-to-sample sliding window for all methods. Table 1 presents the performance of the methods presented with all possible starting times of the sag event.

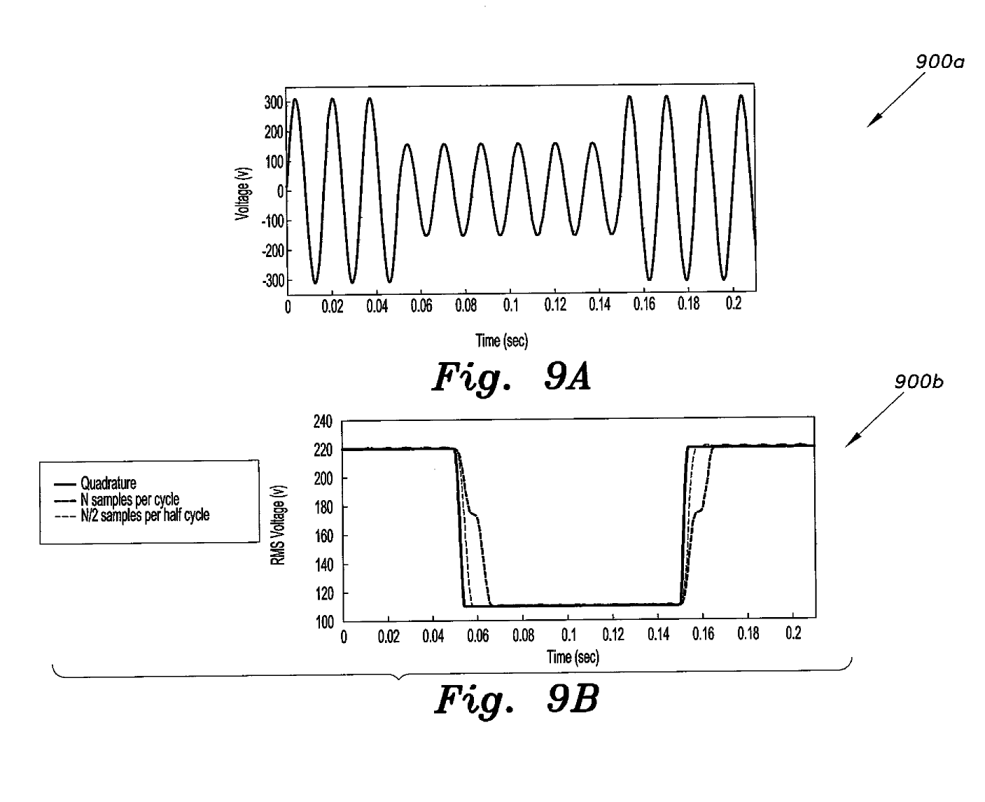

The results given in Table 1 demonstrate clearly that the best results are achieved by the present method for any expected starting time of the voltage sag. The average error observed is 1.39 ms and standard deviation equals 0.05, which demonstrates the robustness of the present quadrature method. The performance of different methods is compared in FIGS. 9A-9B, 900a-900b. The present method has the best performance in terms of detection accuracy.

TABLE 1
Voltage Sag Detection Method Comparisons

| Electrical degrees from | rms calculation methods | | |
|---|---|---|---|
| cross zero point of | Proposed | N/2 samples | N samples |
| instantaneous | Quadrature | per half-cycle | per cycle |
| voltage waveform | (ms) | (ms) | (ms) |
| 0 | 101.34 | 102.09 | 108.20 |
| 15 | 101.34 | 102.13 | 108.20 |
| 30 | 101.34 | 102.09 | 108.24 |
| 45 | 101.39 | 102.18 | 108.24 |
| 60 | 101.44 | 102.64 | 108.24 |
| 75 | 101.44 | 105.84 | 108.29 |
| 90 | 101.44 | 106.07 | 109.08 |
| 105 | 101.44 | 105.79 | 108.29 |
| 120 | 101.44 | 102.64 | 108.24 |
| 135 | 101.39 | 102.18 | 108.24 |
| 150 | 101.34 | 102.13 | 108.24 |
| 165 | 101.34 | 102.13 | 108.24 |
| 180 | 101.34 | 102.09 | 108.20 |
| 195 | 101.34 | 102.13 | 108.20 |
| 210 | 101.34 | 102.09 | 108.24 |
| 225 | 101.39 | 102.18 | 108.24 |
| 240 | 101.44 | 102.64 | 108.24 |
| 255 | 101.44 | 105.84 | 108.29 |
| 270 | 101.44 | 106.07 | 109.08 |
| 285 | 101.44 | 105.79 | 108.29 |
| 300 | 101.44 | 102.64 | 108.24 |
| 315 | 101.39 | 102.18 | 108.24 |
| 330 | 101.34 | 102.13 | 108.24 |
| 345 | 101.34 | 102.13 | 108.24 |
| Best | 101.34 | 102.09 | 108.20 |
| Worst | 101.44 | 106.07 | 109.08 |
| Average | 101.39 | 103.16 | 108.31 |
| Standard Deviation | 0.05 | 1.63 | 0.24 |

Voltage interruption occurs when the rms voltage decreases to less than 10% of nominal rms value for a time period not exceeding 1.0 min. The voltage interruption event is considered with zero amplitude. Table 2 presents the results of all methods considered with a sample sliding window for all possible starting times of the voltage interruption event.

TABLE 2
Voltage Interruption Detection Method Comparisons

| Electrical degrees from | rms calculation methods | | |
|---|---|---|---|
| cross zero point of | Proposed | N/2 samples | N samples |
| instantaneous | Quadrature | per half-cycle | per cycle |
| voltage waveform | (ms) | (ms) | (ms) |
| 0 | 101.81 | 102.83 | 109.31 |
| 15 | 101.81 | 102.78 | 109.31 |
| 30 | 101.85 | 102.83 | 109.35 |
| 45 | 101.85 | 102.97 | 109.35 |
| 60 | 101.85 | 105.65 | 109.49 |
| 75 | 101.90 | 106.58 | 110.05 |
| 90 | 101.90 | 106.72 | 113.01 |
| 105 | 101.90 | 106.58 | 110.00 |
| 120 | 101.85 | 105.60 | 109.49 |
| 135 | 101.85 | 102.97 | 109.35 |
| 150 | 101.85 | 102.83 | 109.31 |
| 165 | 101.81 | 102.78 | 109.31 |
| 180 | 101.81 | 102.83 | 109.31 |
| 195 | 101.81 | 102.78 | 109.31 |
| 210 | 101.85 | 102.83 | 109.35 |
| 225 | 101.85 | 102.97 | 109.35 |
| 240 | 101.85 | 105.65 | 109.49 |
| 255 | 101.90 | 106.58 | 110.05 |
| 270 | 101.90 | 106.72 | 113.01 |
| 285 | 101.90 | 106.58 | 110.00 |
| 300 | 101.85 | 105.60 | 109.49 |
| 315 | 101.85 | 102.97 | 109.35 |
| 330 | 101.85 | 102.83 | 109.31 |
| 345 | 101.81 | 102.78 | 109.31 |
| Best | 101.81 | 102.78 | 109.31 |
| Worst | 101.90 | 106.72 | 113.01 |
| Average | 101.85 | 104.26 | 109.76 |
| Standard Deviation | 0.03 | 1.73 | 1.03 |

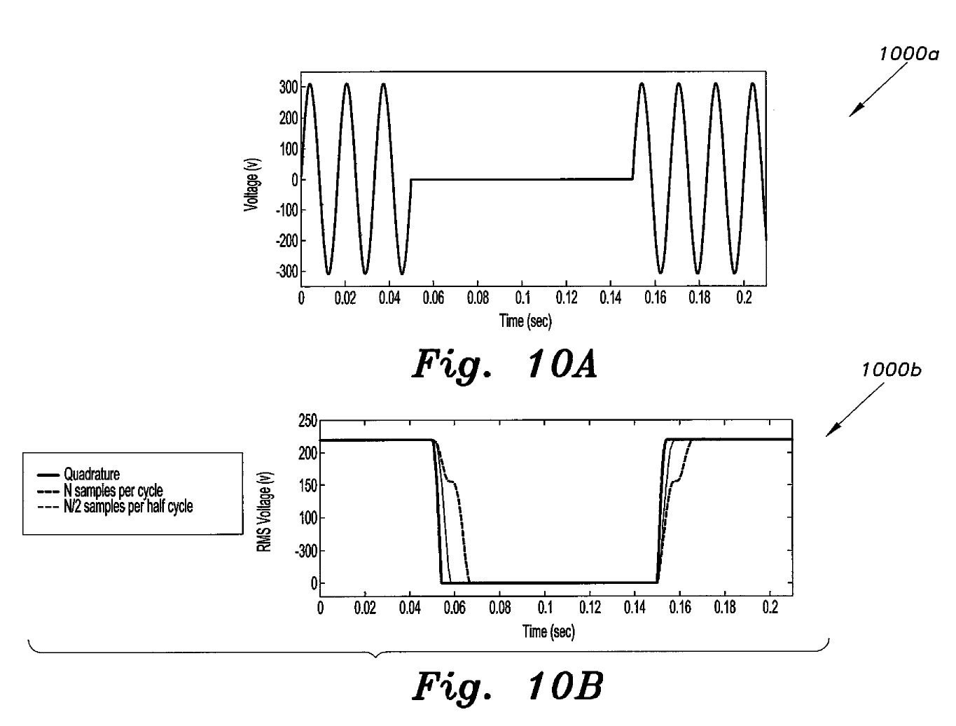

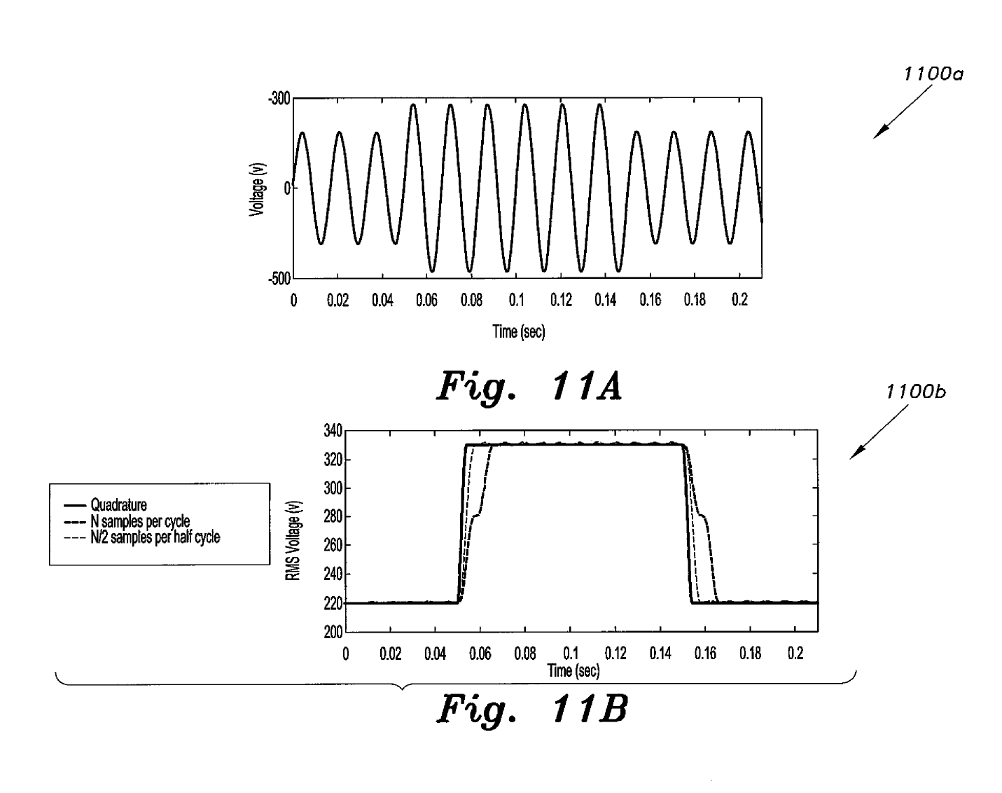

The best result was achieved by the present method for any expected starting time of the voltage interruption. The average error observed for the duration of the event is 1.85 ms with a standard deviation equal to 0.03, which confirms the superiority and robustness of the present method. The average error in other methods is much higher than that of the present method. In addition, FIGS. 10A-10B plots 10a-10b show that the performance of the present method is much superior compared with conventional methods in terms of high-speed response in identifying the event.

Generally, the voltage swell occurs when the rms voltage increases above 110% and less than 180% of nominal rms value for durations of 0.5 cycles to 1.0 minute. A 150% increase in voltage magnitude is considered in this case. Table 3 presents the results of the discussed methods with all expected starting times of the voltage swell event. The best results are obtained with the present method for any expected starting time of the voltage swell.

TABLE 3
Voltage Swell Detection Method Comparisons

| Electrical degrees from | rms calculation methods | | |
|---|---|---|---|
| cross zero point of | Proposed | N/2 samples | N samples |
| instantaneous | Quadrature | per half-cycle | per cycle |
| voltage waveform | (ms) | (ms) | (ms) |
| 0 | 101.81 | 102.83 | 109.31 |
| 15 | 101.81 | 102.78 | 109.31 |
| 30 | 101.85 | 102.83 | 109.35 |
| 45 | 101.85 | 102.97 | 109.35 |
| 60 | 101.85 | 105.65 | 109.49 |
| 75 | 101.90 | 106.58 | 110.05 |
| 90 | 101.90 | 106.72 | 113.01 |
| 105 | 101.90 | 106.58 | 110.00 |
| 120 | 101.85 | 105.60 | 109.49 |
| 135 | 101.85 | 102.97 | 109.35 |
| 150 | 101.85 | 102.83 | 109.31 |
| 165 | 101.81 | 102.78 | 109.31 |
| 180 | 101.81 | 102.83 | 109.31 |
| 195 | 101.81 | 102.78 | 109.31 |
| 210 | 101.85 | 102.83 | 109.35 |
| 225 | 101.85 | 102.97 | 109.35 |
| 240 | 101.85 | 105.65 | 109.49 |
| 255 | 101.90 | 106.58 | 110.05 |
| 270 | 101.90 | 106.72 | 113.01 |
| 285 | 101.90 | 106.58 | 110.00 |
| 300 | 101.85 | 105.60 | 109.49 |
| 315 | 101.85 | 102.97 | 109.35 |
| 330 | 101.85 | 102.83 | 109.31 |
| 345 | 101.81 | 102.78 | 109.31 |
| Best | 101.81 | 102.78 | 109.31 |
| Worst | 101.90 | 106.72 | 113.01 |
| Average | 101.85 | 104.26 | 109.76 |
| Standard Deviation | 0.03 | 1.73 | 1.03 |

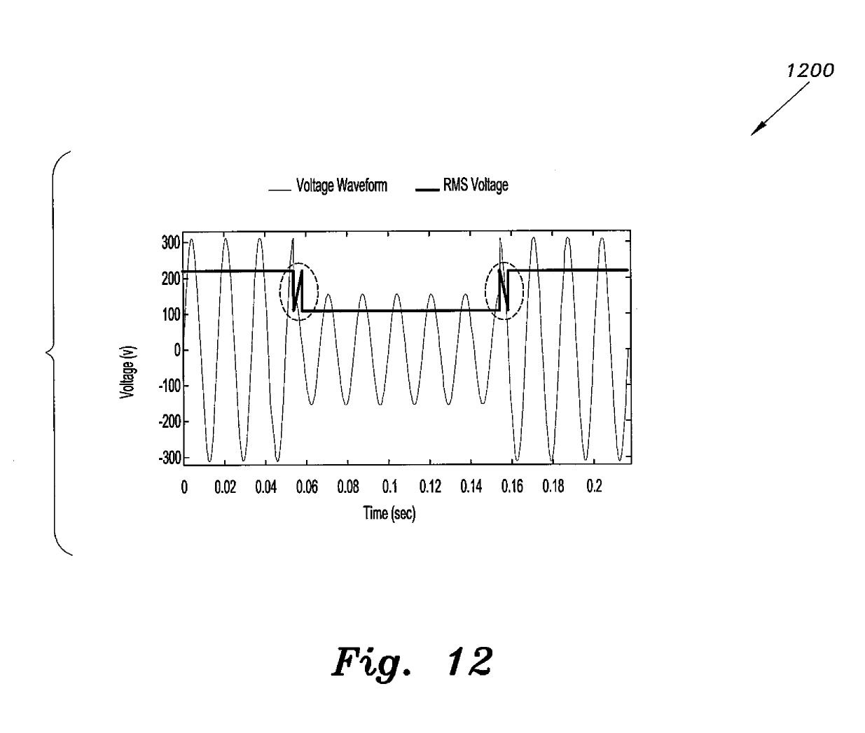

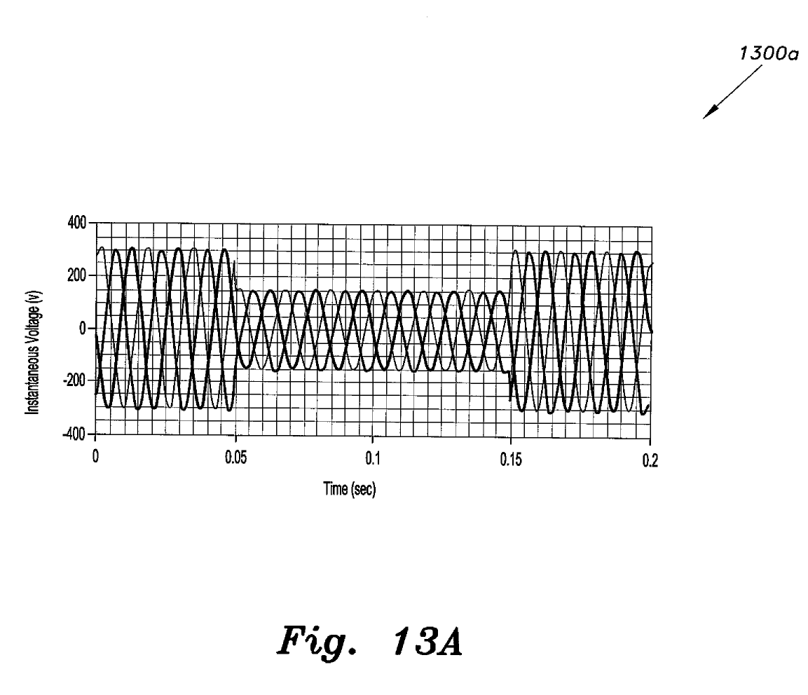

The average error in estimation of the event duration is 0.19 ms with a standard deviation of 0.04. Compared with conventional method results, the present method is far more accurate, superior, and robust. FIGS. 11A-11B plots 1100a-1100b show the performance of all methods and demonstrate that the present method is the fastest to identify the event.

Table 1 shows that the worst performance of the present method occurs if the voltage sag event starts close to the positive and negative peaks of the voltage waveform. FIG. 12, plot 1200 shows the performance of the present method if the event starts at the positive peak of the waveform. It was observed that there are some ripples in rms calculation at starting time and end time of the event. However, these ripples have limited impact on voltage characterization, since the error in the estimated duration is only 1.44 ms.

To verify the effectiveness of the present method, the experimental implementation has been carried out using LabVIEW and the setup described above. The test signal that is utilized to evaluate the experimental real-time performance of the present technique is generated by the programmable AC source.

The test signals include 12 cycles with rated voltage equals to 220V, 60 Hz and sampling frequency equals to 10 kHz (166 sample/cycle). The event duration for each considered voltage event is 6 cycles (100 ms) that occurs at 50 ms and ends at 150 ms.

Experimentally, the results of the present quadrature method with a half-cycle sliding window have been compared with the results of the IEEE and IEC method that utilizes the rms voltage measured over one cycle, commencing at a fundamental zero crossing, and refreshed each half cycle. Results were also compared with the method used until now in the majority of PQ-instruments, which utilizes the rms voltage measured over one cycle and refreshed each cycle. Similar to the simulation, the sag, interruption, and swell voltage events are examined experimentally

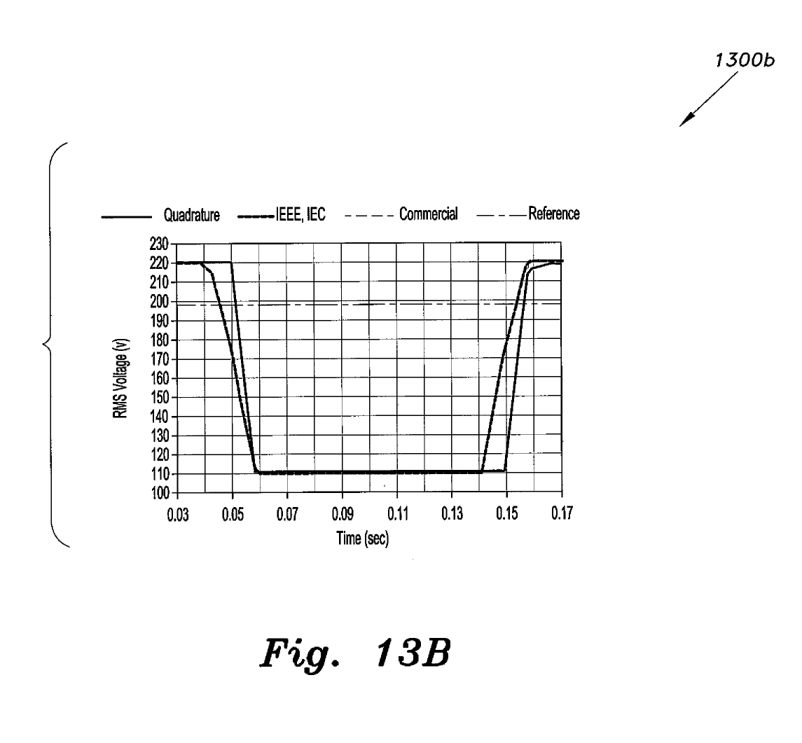

Regarding Voltage Sag Case 1, FIGS. 13A-13B, plots 1300a, 1300b show the experimental real time results of the voltage sag detection and characterization based on rms voltage values utilizing the three considered methods. FIG. 13A shows the instantaneous waveform of three-phase voltage sag. FIG. 13B shows the results of the three methods as well as the reference voltage of detecting the voltage sag at 0.9 per-unit (pu), i.e., 198V. The voltage sag occurs at 50 ms and ends at 150 ms. The estimated start time and end time of the voltage sag using the present and commercial methods are almost the same, which are 51 ms and 157 ms respectively, while the estimated start time using the IEEE method is 45 ms and the end time is 154 ms.

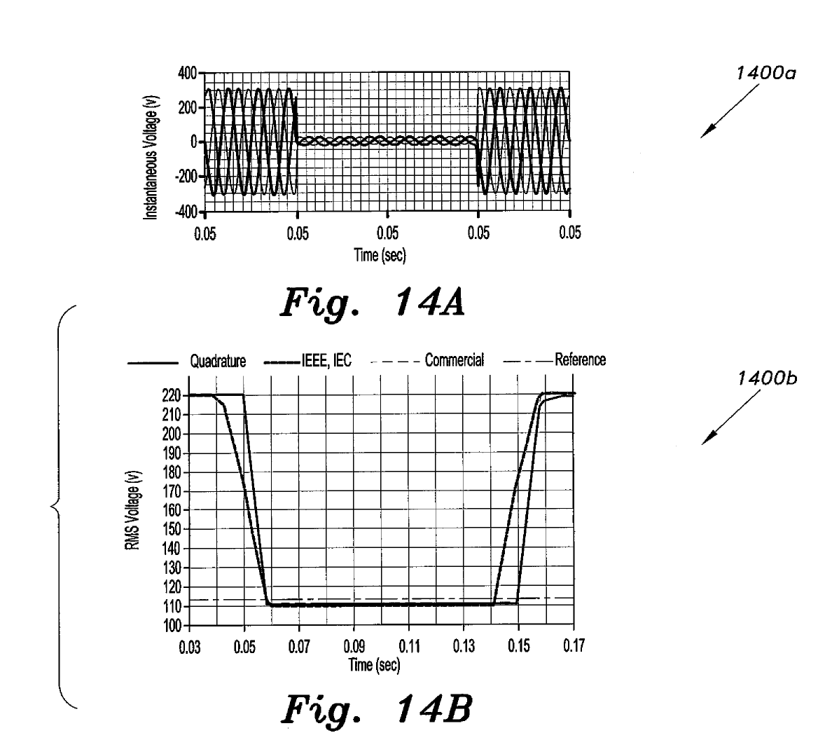

Regarding Voltage Interruption Case 2, the instantaneous voltage interruption waveforms and the real-time tracking rms magnitudes of the event using the considered methods are shown as plots 1400a and 1400b in FIGS. 14A-14B, respectively. The results of the three methods for trending the voltage interruption and the reference voltage of detecting the voltage interruption that is 0.1 pu (22 Volts) are shown in FIG. 14B. The estimated start time of the voltage interruption using the three methods is almost the same, viz., 58 ms. The estimated end time using the IEEE method is 141 ms, whereas the estimated end time using the present and commercial methods is the same, viz., 150 ms.

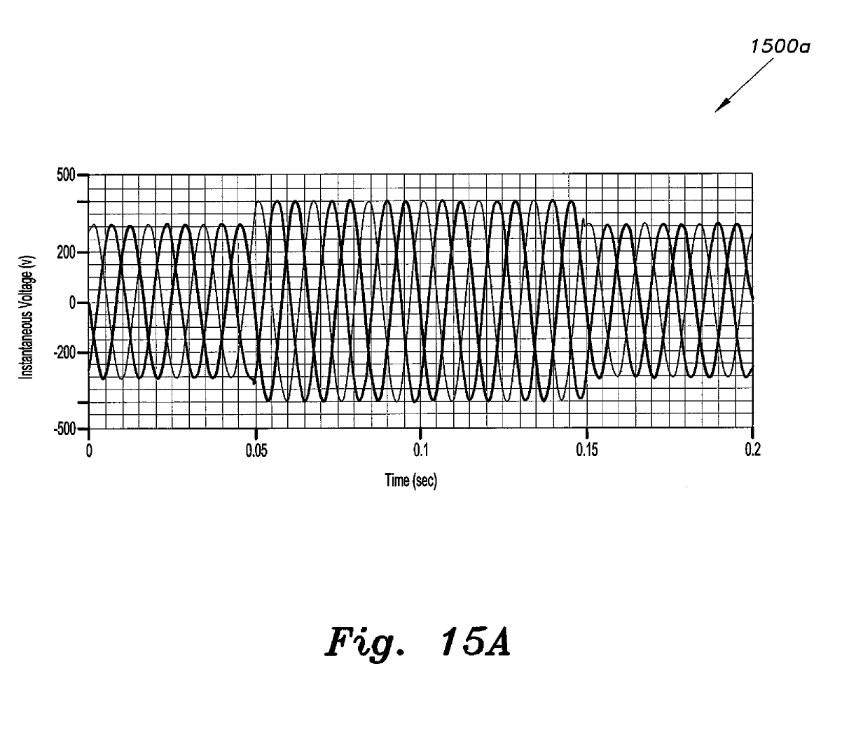

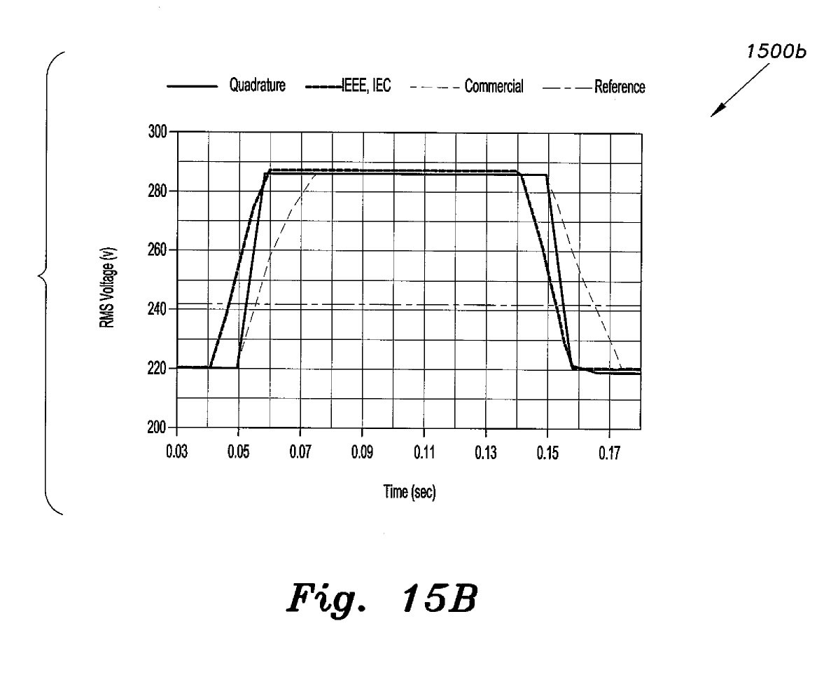

Regarding Voltage Swell Case 3, FIGS. 15A-15b, plots 1500a, 1500b show the instantaneous voltage swell waveforms and the real-time results of the three considered methods for detecting and localizing the voltage swell. FIG. 15B shows the results of the considered methods for detecting the voltage swell and the reference voltage of detecting the event that is 1.1 pu, i.e., 286 Volts. The estimated start time of the voltage swell using the IEEE method is 47 ms, using the present method is 52 ms, and using the commercial method is 54 ms. The estimated end time using the IEEE method is 153 ms, whereas the estimated end time using the present and commercial methods is 155 ms and 166 ms, respectively.

It is clear that the present method has more accurate detection of the event in terms of start, stop, and duration times. It is quite evident that the present method with half-cycle sliding window gives encouraging results compared with the results of the other two methods.

In the present quadrature method for calculating the rms value of the voltage waveform in power quality events is developed and implemented. The present method needs only two samples per half cycle, which enhances its online applicability. The quadrature method has been examined experimentally on sag, swell, and interruption voltage events. The results have been compared with those of the conventional methods. The simulation results as well as the experimental results demonstrate the accuracy, superiority, and robustness of the present method in all cases considered.

It is to be understood that the present invention is not limited to the embodiments described above, but encompasses any and all embodiments within the scope of the following claims.

We claim:

1. A quadrature-based voltage events detection method, comprising the steps of:
(a) taking a first sample S₁ of an alternating current (AC) voltage waveform;
(b) taking a second sample S₂ of the alternating current voltage waveform, the second sample being taken 90° from the first sample;
(c) computing an rms value based on the first and second samples, the rms value being characterized by the relation:
$${V}_{r m s} = \frac{{V}_{p}}{\sqrt{2}} = \frac{\sqrt{{S}_{1}^{2} + {S}_{2}^{2}}}{\sqrt{2}} ,$$
where Vₚ is the peak value of the voltage waveform, Vᵣₘₛ is the rms value of the voltage waveform, and S₁ and S₂ are the voltages of first and second samples, respectively;
(d) comparing the computed rms value to a nominal rms value of the voltage waveform; and
(e) identifying a voltage fault event when the computed rms value deviates from the nominal rms value.

2. The quadrature-based voltage events detection method according to claim 1, wherein said step of identifying a voltage fault event comprises identifying the voltage fault event as a voltage swell event when the computed rms value deviates from the nominal rms value by increasing to between about 110% and 180% of the nominal rms value for a predetermined time period.

3. The quadrature-based voltage events detection method according to claim 1, wherein said step of identifying a voltage fault event comprises identifying the voltage fault event as a voltage sag event when the computed rms value deviates from the nominal rms value by settling to between about 10% and 90% of the nominal rms value for a predetermined time period.

4. The quadrature-based voltage events detection method according to claim 1, wherein said step of identifying a voltage fault event comprises identifying the voltage fault event as a voltage interruption event when the computed rms value deviates from the nominal rms value by settling to approximately less than 10% of the nominal rms value for a predetermined time period.

5. The quadrature-based voltage events detection method according to claim 1, further comprising the step of estimating a duration of said voltage fault event based on temporal analysis of said rms value deviation from said nominal rms value.

6. The quadrature-based voltage events detection method according to claim 1, further comprising the steps of:
(f) sliding a time value of the first and second sample taken relative to the AC voltage waveform, the sliding time value being based on multiples of about 15° electrical phase difference from a zero crossing point of the voltage waveform; and
(g) repeating steps (a) through (e) after performing step (f) for continuous monitoring.
